(19) United States
(12) Patent Application Publication
(10) Pub. No.: US 2017/0179232 A1
(43) Pub. Date: Jun. 22, 2017

(54) III-V TRANSISTOR DEVICE WITH DOPED BOTTOM BARRIER

(71) Applicant: INTERNATIONAL BUSINESS MACHINES CORPORATION, Armonk, NY (US)

(72) Inventors: Cheng-Wei Cheng, White Plains, NY (US); Pranita Kerber, Mount Kisco, NY (US); Amlan Majumdar, White Plains, NY (US); Yanning Sun, Scarsdale, NY (US)

(21) Appl. No.: 14/974,182

(22) Filed: Dec. 18, 2015

(51) Int. Cl. H01L 29/10; H01L 29/417; H01L 29/78; H01L 29/45; H01L 21/02; H01L 29/66; H01L 21/265

(52) U.S. Cl. CPC H01L 29/1079; H01L 29/66545; H01L 29/41783; H01L 21/26546; H01L 29/66522; H01L 29/665; H01L 29/452; H01L 21/02387; H01L 21/02538; H01L 29/78

(57) ABSTRACT

A method for forming a semiconductor device comprising forming a sacrificial gate stack on a channel region of first layer of a substrate, forming a spacer adjacent to the sacrificial gate stack, forming a raised source/drain region on the first layer of the substrate adjacent to the spacer, forming a dielectric layer over the raised source/drain region, removing the sacrificial gate stack to expose the channel region of the first layer of the substrate, and implanting dopants in a second layer of the substrate to form an implant region in the second layer below the channel region of the first layer of the substrate, where the first layer of the substrate is arranged on the second layer of the substrate.

### BACKGROUND

The present invention generally relates to metal oxide semiconductor field effect transistor (MOSFET) devices, and more specifically, to MOSFET devices with a doped bottom barrier layer.

The MOSFET is a transistor used for amplifying or switching electronic signals. The MOSFET has a source, a drain, and a metal oxide gate electrode. The metal gate is electrically insulated from the main semiconductor n-channel or p-channel by a thin layer of insulating material, for example, silicon dioxide or glass, which makes the input resistance of the MOSFET relatively high. The gate voltage controls whether the path from drain to source is an open circuit (“off”) or a resistive path (“on”).

N-type field effect transistors (NFET) and p-type field effect transistors (PFET) are two types of complementary MOSFETs. The NFET uses electrons as the current carriers and with n-doped source and drain junctions. The PFET uses holes as the current carriers and with p-doped source and drain junctions.

In conventional III-V MOSFET devices, short-channel effects are improved by incorporating a heavily doped p-type bottom barrier layer. The heavily doped p-type bottom barrier layer is often epitaxially grown entirely under the source/drain contact region.

### SUMMARY

According to an embodiment of the present invention, a method for forming a semiconductor device comprising forming a sacrificial gate stack on a channel region of first layer of a substrate, forming a spacer adjacent to the sacrificial gate stack, forming a raised source/drain region on the first layer of the substrate adjacent to the spacer, forming a dielectric layer over the raised source/drain region, removing the sacrificial gate stack to expose the channel region of the first layer of the substrate, and implanting dopants in a second layer of the substrate to form an implant region in the second layer below the channel region of the first layer of the substrate, where the first layer of the substrate is arranged on the second layer of the substrate.

According to another embodiment of the present invention, a method for forming a semiconductor device comprises forming a sacrificial gate stack on a channel region of first layer of a substrate, forming a spacer adjacent to the sacrificial gate stack, removing exposed portions of the first layer of the substrate to expose portions of a second layer of the substrate, forming an insulator region on portions of the second layer of the substrate, forming a raised source/drain region on the second layer of the substrate adjacent to the spacer, forming a dielectric layer over the raised source/drain region, removing the sacrificial gate stack to expose the channel region of the first layer of the substrate, and implanting dopants in a second layer of the substrate to form an implant region in the second layer below the channel region of the first layer of the substrate, where the first layer of the substrate is arranged on the second layer of the substrate.

According to yet another embodiment of the present invention, a semiconductor device comprises a gate stack arranged on a channel region of a first layer of a substrate, a spacer arranged adjacent to the gate stack on the first layer of the substrate, an epitaxially grown source/drain region arranged on the first layer of the substrate adjacent to the spacer, and an implant region arranged below the channel region of the first layer of the substrate, the implant region arranged in a second layer of the substrate, the first layer of the substrate arranged on the second layer of the substrate.

### BRIEF DESCRIPTION OF THE DRAWINGS

FIGS. 1-10 illustrate an exemplary method for forming an exemplary embodiment of a MOSFET device.

FIG. 1 illustrates a cutaway view of a substrate.

FIG. 2 illustrates a cutaway view following the formation of a trench.

FIG. 3 illustrates a cutaway view following the formation of shallow trench isolation regions.

FIG. 4 illustrates a cutaway view following the formation of a sacrificial gate stack and spacers.

FIG. 5 illustrates a cutaway view following the formation of source/drain extension regions.

FIG. 6 illustrates a cutaway view of the resultant structure following the formation of raised source/drain regions.

FIG. 7 illustrates a cutaway view following the formation of a silicide over portions of the raised source/drain regions.

FIG. 8 illustrates a cutaway view of the resultant structure following the formation of an inter-level dielectric (ILD) layer.

FIG. 9 illustrates a cutaway view of the formation of an implant region in the III-V material bottom barrier layer.

FIG. 10 illustrates a cutaway view of the resultant MOSFET device following the formation of a gate stack and contacts.

FIGS. 11-17 illustrate another exemplary method for forming another exemplary embodiment of a MOSFET device.

FIG. 11 illustrates a cutaway view following the formation of a trench.

FIG. 12 illustrates a cutaway view following the formation of an STI region in the trench of FIG. 11.

FIG. 13 illustrates a cutaway view of a substrate layer, the III-V material bottom barrier layer, the III-V channel layer, sacrificial gate stack, and spacers.

FIG. 14 illustrates the resultant structure following a lithographic patterning and etching process such as, for example, reactive ion etching that removes portions of the STI region.

FIG. 15 illustrates the resultant structure following the formation of raised source/drain regions and silicide regions.

FIG. 16 illustrates structure following the formation of an ILD layer following a deposition process similar to the process described above and an implant region in the III-V material bottom barrier layer.

FIG. 17 illustrates the resultant MOSFET device following the formation of a gate stack that includes a high-k layer and a metal gate.

### DETAILED DESCRIPTION

As discussed above, conventional III-V MOSFET devices, short-channel effects are improved by incorporating a heavily doped p-type bottom barrier layer. The heavily doped p-type bottom barrier layer is often epitaxially grown entirely under the source/drain contact region.

The embodiments described herein provide for III-V MOSFET structures with a p-type doped bottom barrier layer that is self-aligned to the channel region below the gate. The embodiments described herein have desirably low junction capacitance and low band-to-band tunneling currents in the off state in low-bandgap III-V materials.

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

As used herein, the articles “a” and “an” preceding an element or component are intended to be nonrestrictive regarding the number of instances (i.e. occurrences) of the element or component. Therefore, “a” or “an” should be read to include one or at least one, and the singular word form of the element or component also includes the plural unless the number is obviously meant to be singular.

As used herein, the terms “invention” or “present invention” are non-limiting terms and not intended to refer to any single aspect of the particular invention but encompass all possible aspects as described in the specification and the claims.

As used herein, the term “about” modifying the quantity of an ingredient, component, or reactant of the invention employed refers to variation in the numerical quantity that can occur, for example, through typical measuring and liquid handling procedures used for making concentrates or solutions. Furthermore, variation can occur from inadvertent error in measuring procedures, differences in the manufacture, source, or purity of the ingredients employed to make the compositions or carry out the methods, and the like. In one aspect, the term “about” means within 10% of the reported numerical value. In another aspect, the term “about” means within 5% of the reported numerical value. Yet, in another aspect, the term “about” means within 10, 9, 8, 7, 6, 5, 4, 3, 2, or 1% of the reported numerical value.

It will also be understood that when an element, such as a layer, region, or substrate is referred to as being “on” or “over” another element, it can be directly on the other element or intervening elements may also be present. In contrast, when an element is referred to as being “directly on” or “directly over” another element, there are no intervening elements present, and the element is in contact with another element.

It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

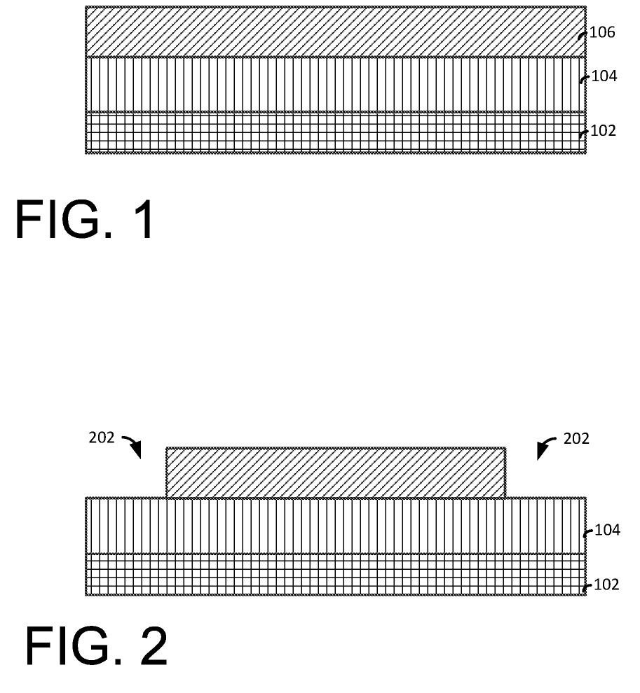

FIGS. 1-10 illustrate an exemplary method for forming an exemplary embodiment of a MOSFET device.

In this regard, FIG. 1 illustrates a cutaway view of a substrate layer 102. Non-limiting examples of suitable substrate materials include Si (silicon), strained Si, SiC (silicon carbide), Ge (geranium), SiGe (silicon germanium), SiGeC (silicon-germanium-carbon), Si alloys, Ge alloys, GaAs (gallium arsenide), InAs (indium arsenide), InP (indium phosphide), or any combination thereof. Other examples of suitable substrates include silicon-on-insulator (SOI) substrates with buried oxide (BOX) layers. A III-V material bottom barrier layer 104 is arranged on the substrate 102. A group III-V material includes, for example, group III elements (e.g., Al, Ga, and In) combined with group V elements (e.g., N, P, As, and Sb). The III-V material bottom barrier layer 104 may be formed by, for example, an epitaxial growth process. A III-V channel layer 106 is formed on the III-V material bottom barrier layer 104.

The bottom barrier layer 104 is a semiconductor material with electron affinity that is less than the electron affinity of the channel layer 106 such that the conduction band of the channel layer 106 is lower in energy than the conduction band of the bottom barrier layer 104. Therefore, the higher-energy bottom barrier layer 104 acts as an energy barrier and the conduction electrons are confined to the lower-energy channel layer 106. Examples of channel/barrier material combinations are, but not limited to, InGaAs/InAlAs, InGaAs/AlGaAs, InGaAs/InP, InAs/InAlAs, InAs/AlGaAs, and InAs/InP.

FIG. 2 illustrates a cutaway view following a lithographic patterning and etching process such as, for example, reactive ion etching that removes portions of the III-V channel layer 106 and exposes portions of the III-V material bottom barrier layer 104 to define trenches 202.

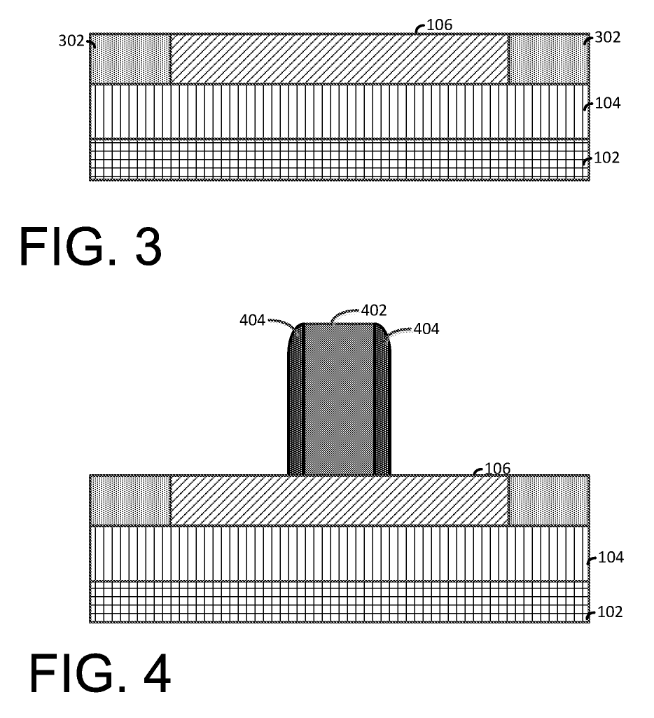

FIG. 3 illustrates a cutaway view following the formation of shallow trench isolation (STI) regions 302. The STI regions 302 are formed by filling the trenches 202 (of FIG. 2) with, for example, an insulating material such as an oxide material. Alternatively, the trenches may be lined with a silicon dioxide liner formed by a thermal oxidation process and then filled with additional silicon dioxide or another material.

Non-limiting examples of suitable oxide materials for the STI regions 302 include silicon dioxide, tetraethylorthosilicate (TEOS) oxide, high aspect ratio plasma (HARP) oxide, silicon oxide, high temperature oxide (HTO), high density plasma (HDP) oxide, oxides formed by an atomic layer deposition (ALD) process, or any combination thereof.

FIG. 4 illustrates a cutaway view following the formation of a sacrificial (dummy) gate stack 402 and spacers 404 adjacent to the sidewalls of the sacrificial gate stack 402. The sacrificial gate stack 402 may be formed by, for example, depositing a layer of amorphous silicon (aSi) or polycrystalline silicon (polysilicon) over the III-V channel layer 106. A hardmask layer (not shown) may be deposited over the layer of aSi or polysilicon in some exemplary embodiments. A lithographic patterning and etching process such as, for example, reactive ion etching is performed to remove exposed portions of the hardmask and layer of aSi or polysilicon, which patterns the sacrificial gate stack 402.

The spacers 404 may be formed by, for example, depositing a layer of spacer material over exposed portions of the III-V channel layer 106 and over the sacrificial gate stack 402. The spacer material can be any dielectric spacer material. Non-limiting examples of suitable materials for the spacers 404 include dielectric oxides (e.g., silicon oxide), dielectric nitrides (e.g., silicon nitride), dielectric oxynitrides, or any combination thereof. The spacer material is deposited by a deposition process, for example, chemical vapor deposition (CVD) or physical vapor deposition (PVD). Following the deposition of the spacer material, an etching process such as, for example reactive ion etching is performed that removes portions of the spacer material to form the spacers 404.

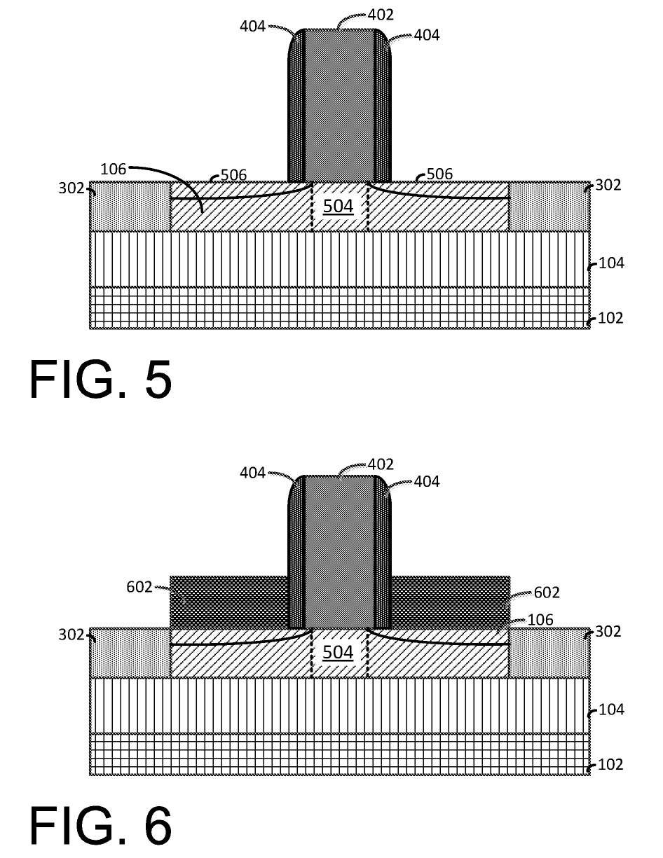

FIG. 5 illustrates a cutaway view following the formation of the spacers 404 source/drain extension regions 506 are formed in the III-V channel layer 106. The source/drain extension regions 506 may be formed by, for example, an ion implantation process that may be performed at an angle to provide a doped region of the III-V channel layer 106 under the spacers 404 and partially under the sacrificial gate stack 402. A channel region 504 is defined under the sacrificial gate stack 402.

FIG. 6 illustrates a cutaway view of the resultant structure following the formation of raised source/drain regions 602 on exposed portions of the III-V channel layer 106. The raised source/drain regions 602 may be formed by, for example, an epitaxial growth process. The underlying III-V channel layer 106 acts as a seed crystal. Epitaxial layers may be grown from gaseous or liquid precursors. Epitaxial silicon may be grown using vapor-phase epitaxy (VPE), molecular-beam epitaxy (MBE), liquid-phase epitaxy (LPE), or other suitable process. The epitaxial silicon, silicon germanium, and/or carbon doped silicon (Si:C) silicon can be doped during deposition by adding a dopant or impurity to form a silicide. The silicon may be doped with an n-type dopant (e.g., phosphorus or arsenic) or a p-type dopant (e.g., boron or gallium), depending on the type of transistor. Alternatively, following the epitaxial growth process, the raised source/drain regions 602 may be doped using an ion implantation process.

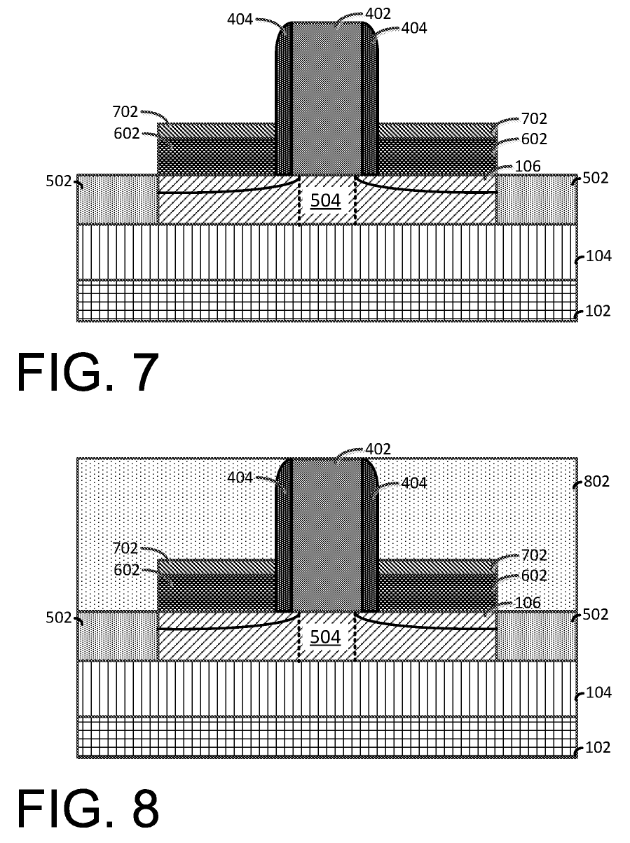

FIG. 7 illustrates a cutaway view following the formation of a silicide 702 over portions of the raised source/drain regions 602. To form the silicide 702, a metallic film is deposited and annealed. The metallic film can be deposited by performing an evaporation process or a sputtering process. The metallic film is annealed by heating inside a furnace or performing a rapid thermal treatment in an atmosphere containing pure inert gases (e.g., nitrogen or argon) so that the metal reacts with exposed silicon in the substrate raised source/drain regions 602 to form the metal silicide 702 layer. Non-limiting examples of suitable metal silicide materials include titanium silicide, tungsten silicide, cobalt silicide, nickel silicide, molybdenum silicide, platinum silicide, or any combination thereof.

FIG. 8 illustrates a cutaway view of the resultant structure following the formation of an inter-level dielectric (ILD) layer 802. Following the formation of the silicide 702, the ILD layer 802 is formed over the exposed portions of the STI region 502, the raised source/drain regions 602, silicide layer 702, and the spacers 404. The inter-level dielectric (ILD) layer 802 may be formed from, for example, a low-k dielectric oxide, including but not limited to, silicon dioxide, spin-on-glass, a flowable oxide, a high density plasma oxide, borophosphosilicate glass (BPSG), or any combination thereof. The ILD layer 802 may further comprise a liner (e.g., silicon nitride) (not shown) that is deposited before the oxide.

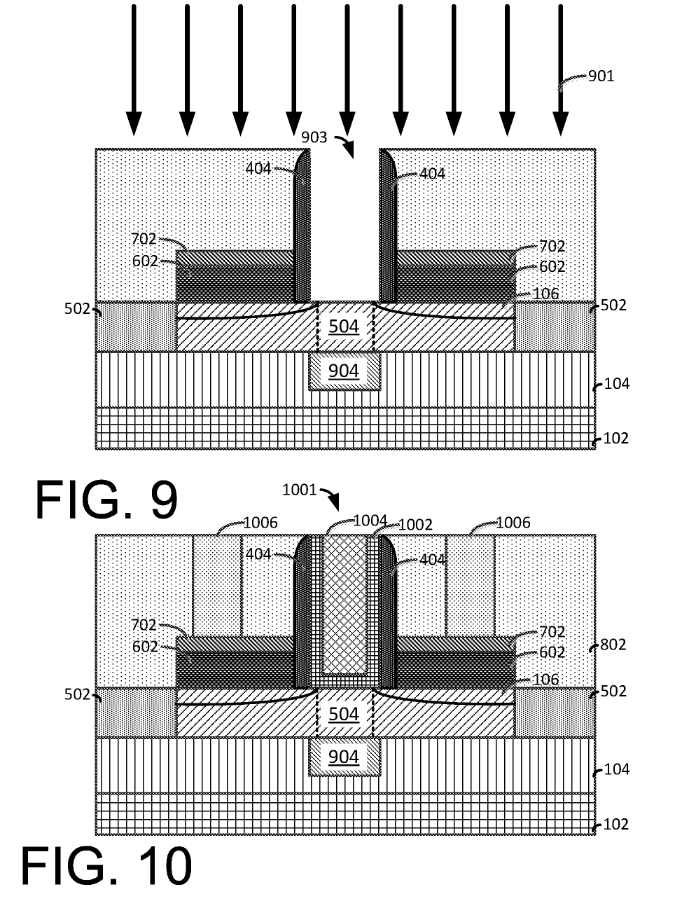

FIG. 9 illustrates a cutaway view of the formation of an implant region 904 in the III-V material bottom barrier layer 104 below the channel region 504. The implant region 904 is formed by removing the sacrificial gate stack 202 using a suitable selective etching process such as, for example, reactive ion etching that forms a cavity 903 and exposes the channel region 504. Ions 901 are implanted in a portion of the III-V material bottom barrier layer 104 using an ion implantation process that implants p-type dopants. The ion implantation process results in an implant region 904 that is self-aligned to the channel region 504. The implant region has a relatively high concentration of dopants of greater than about 10¹⁹ per cubic centimeter.

FIG. 10 illustrates a cutaway view of the resultant MOSFET device following the formation of a gate stack 1001 and contacts 1006. In this regard, the gate stack 1001 includes a high-k metal gate formed, for example, by filling the cavity 903 (of FIG. 9) with one or more high-k dielectric layers 1002, one or more workfunction metals 1004, and one or more metal gate conductor materials (not shown). The high-k dielectric material(s) can be a dielectric material having a dielectric constant greater than 4.0, 7.0, or 10.0. Non-limiting examples of suitable materials for the high-k dielectric material include oxides, nitrides, oxynitrides, silicates (e.g., metal silicates), aluminates, titanates, nitrides, or any combination thereof. Examples of high-k materials include, but are not limited to, metal oxides such as hafnium oxide, hafnium silicon oxide, hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate. The high-k material may further include dopants such as, for example, lanthanum and aluminum.

The high-k dielectric material layer 1002 may be formed by suitable deposition processes, for example, chemical vapor deposition (CVD), plasma-enhanced chemical vapor deposition (PECVD), atomic layer deposition (ALD), evaporation, physical vapor deposition (PVD), chemical solution deposition, or other like processes. The thickness of the high-k dielectric material may vary depending on the deposition process as well as the composition and number of high-k dielectric materials used. The high-k dielectric material layer 1002 may have a thickness in a range from about 0.5 to about 20 nm.

The work function metal(s) 1004 may be disposed over the high-k dielectric material. The type of work function metal(s) depends on the type of transistor and may differ between the NFET 101 and the PFET 102. Non-limiting examples of suitable work function metals 1004 include p-type work function metal materials and n-type work function metal materials. P-type work function materials include compositions such as ruthenium, palladium, platinum, cobalt, nickel, and conductive metal oxides, or any combination thereof. N-type metal materials include compositions such as hafnium, zirconium, titanium, tantalum, aluminum, metal carbides (e.g., hafnium carbide, zirconium carbide, titanium carbide, and aluminum carbide), aluminides, or any combination thereof.

A conductive metal (not shown) is deposited over the high-k dielectric material(s) and workfunction layer(s) to form the gate stacks. Non-limiting examples of suitable conductive metals include aluminum (Al), platinum (Pt), gold (Au), tungsten (W), titanium (Ti), or any combination thereof. The conductive metal may be deposited by a suitable deposition process, for example, CVD, PECVD, PVD, plating, thermal or e-beam evaporation, and sputtering.

A planarization process, for example, chemical mechanical planarization (CMP), is performed to polish the surface of the conductive gate metal.

Following the formation of the gate stack 1001, contacts 1006 are formed by forming contact trenches (not shown) in the ILD layer 802 that expose portions of the silicide 702 using a suitable patterning and etching process such as, for example, reactive ion etching. Following the formation of the contact trenches, a liner layer (not shown) may be deposited in the contact trenches. Conductive material is deposited in the contact trenches and planarized using a planarization process such as, for example, chemical mechanical polishing that defines the contacts 1006. The conductive material may include, for example, copper, aluminum, silver, or other suitable conductive materials.

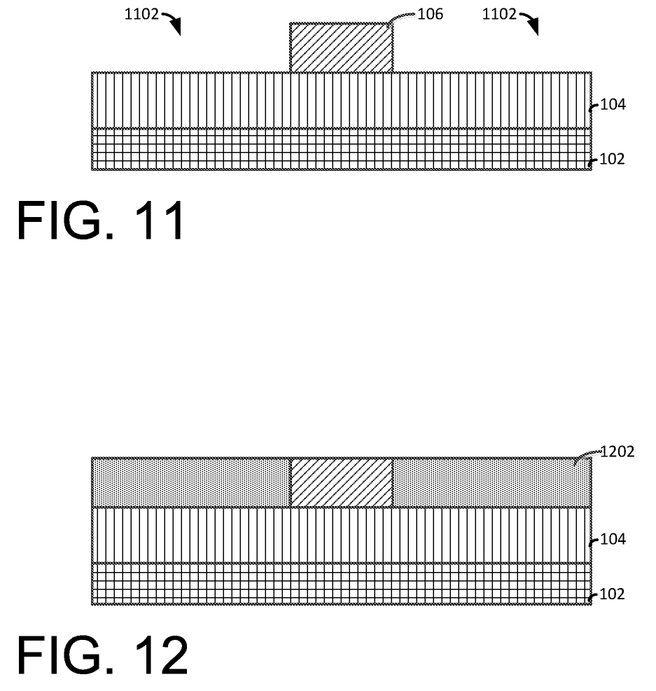

FIGS. 11-17 illustrate another exemplary method for forming another exemplary embodiment of a MOSFET device.

Referring to FIG. 11, FIG. 11 illustrates a cutaway view of a substrate layer 102, the material bottom barrier layer 104, and the III-V channel layer 106. A trench 1102 has been formed by patterning and etching to remove portions of the III-V channel layer 106 and expose portions of the III-V material bottom barrier layer 104.

FIG. 12 illustrates the formation of an STI region 1202 in the trench 1102 (of FIG. 11) using a process similar to the process described above.

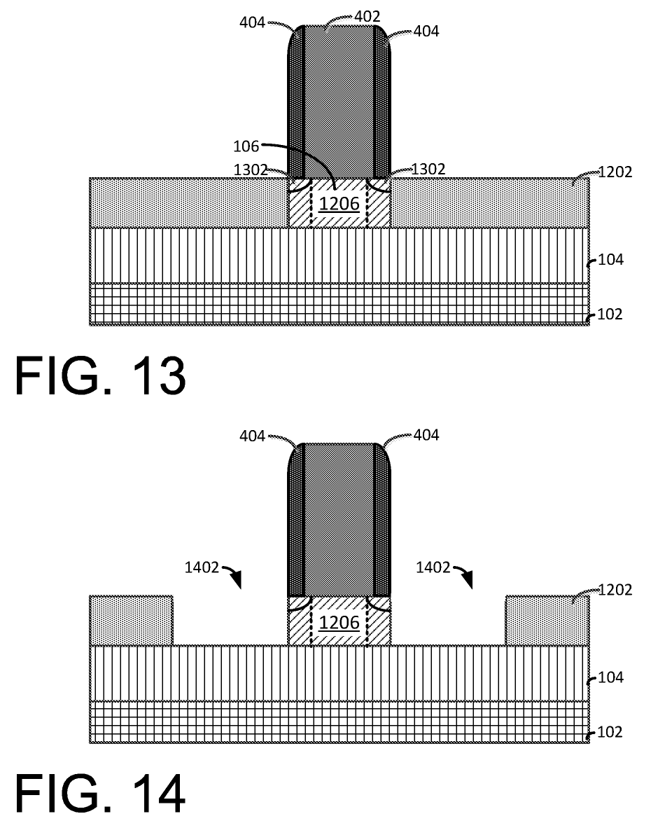

FIG. 13 illustrates the resultant structure where a sacrificial gate stack 402 and spacers 404 are arranged on the III-V channel layer 106. The substrate layer 102, the III-V material bottom barrier layer 104, the III-V channel layer 106, sacrificial gate stack 402, and spacers 404 have been formed similar processes as described above.

Following the formation of the spacers 404, source/drain extension regions 1302 may be formed in the III-V channel layer 106 using, for example, an ion implantation and annealing process as described above. A channel region 1206 in the III-V channel layer 106 is shown under the sacrificial gate stack 404.

FIG. 14 illustrates the resultant structure following a lithographic patterning and etching process such as, for example, reactive ion etching that removes portions of the STI region 1202 to form cavities 1402 that expose portions of the III-V material bottom barrier layer 104.

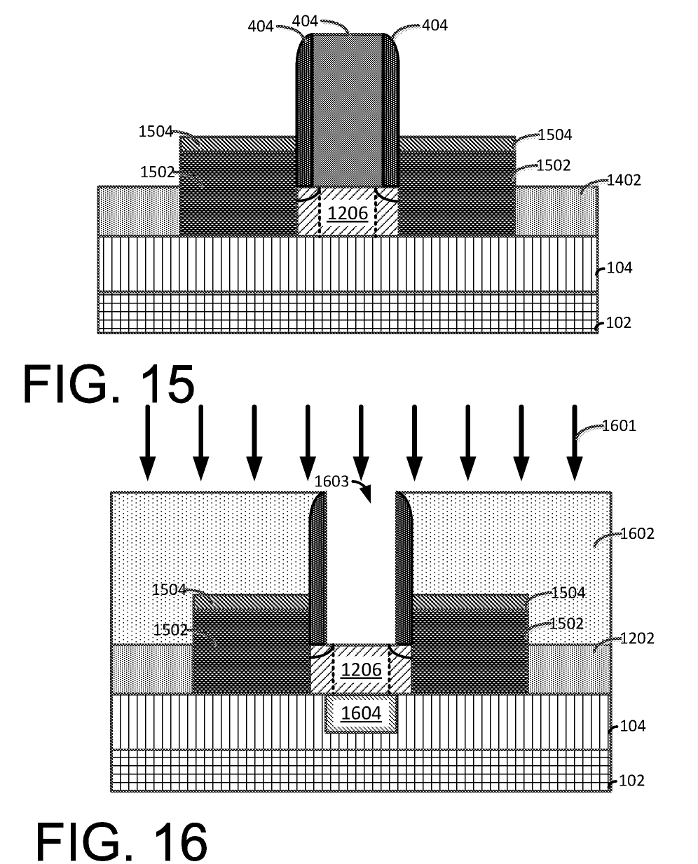

FIG. 15 illustrates the resultant structure following the formation of raised source/drain regions 1502 and silicide regions 1504 using a similar process as described above. In this regard, the raised source/drain regions 1502 are seeded from the exposed portions of the III-V material bottom barrier layer 104 and fill the cavities 1402 (of FIG. 14).

FIG. 16 illustrates structure following the formation of an ILD layer 1602 following a deposition process similar to the process described above. Following the formation of the ILD layer 1602, the sacrificial gate stack 404 (of FIG. 15) is removed, which exposes the channel region 1206 of the III-V channel layer 106. An ion implantation process implants ions 1601 to form a doped implant region 1604 in the III-V material bottom barrier layer 104 below the channel region 1206 using a process as described above.

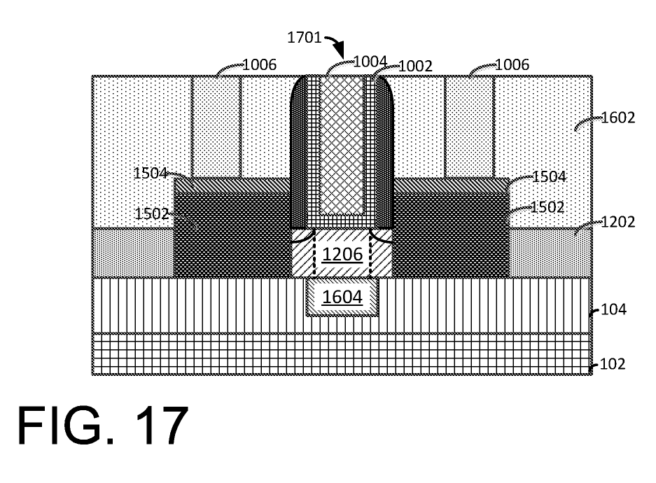

FIG. 17 illustrates the resultant MOSFET device following the formation of a gate stack 1701 that includes a high-k layer 1002 and a metal gate 1004 in a similar manner as described above. Following the formation of the gate stack 1701 contacts 1006 may be formed.

The embodiments described herein provide for III-V MOSFET structures with a p-type doped bottom barrier layer that is self-aligned to the channel region below the gate. The embodiments described herein have desirably low junction capacitance and low band-to-band tunneling currents in the off state in low-bandgap III-V materials.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. A method for forming a semiconductor device, the method comprising:
forming a sacrificial gate stack on a channel region of a first layer of a substrate;
forming a spacer adjacent to the sacrificial gate stack;
forming a raised source/drain region on the first layer of the substrate adjacent to the spacer after forming the spacer adjacent to the sacrificial gate stack;
forming a silicide region on the source/drain region;
forming a dielectric layer over the raised source/drain region after forming the silicide region on the source/drain region;
removing the sacrificial gate stack to expose the channel region of the first layer of the substrate; and
implanting dopants in a second layer of the substrate to form an implant region in the second layer below the channel region of the first layer of the substrate, where the first layer of the substrate is arranged on the second layer of the substrate.

2. The method of claim 1, further comprising forming a metal gate stack on the channel region of the first layer of the substrate.

3. The method of claim 1, wherein the forming the raised source/drain region includes growing a doped semiconductor material on an exposed portion of the first layer of the substrate.

4. A method for forming a semiconductor device, the method comprising:
forming a sacrificial gate stack on a channel region of a first layer of a substrate;
forming a spacer adjacent to the sacrificial gate stack;
forming a doped source/drain extension region in the first layer of the substrate;
forming a raised source/drain region on the first layer of the substrate adjacent to the spacer after forming the doped source/drain extension region in the first layer of the substrate;
forming a dielectric layer over the raised source/drain region;
removing the sacrificial gate stack to expose the channel region of the first layer of the substrate; and
implanting dopants in a second layer of the substrate to form an implant region in the second layer below the channel region of the first layer of the substrate, where the first layer of the substrate is arranged on the second layer of the substrate,
wherein each of the first layer of the substrate and the second layer of the substrate includes a III-V semiconductor material.

5. The method of claim 1, wherein the second layer of the substrate includes a III-V semiconductor material layer.

6. The method of claim 1, wherein the dopants include p-type dopants.

7. The method of claim 4, further comprising forming a silicide region on the source/drain region prior to forming the dielectric layer over the raised source/drain region.

8. method for forming a semiconductor device, the method comprising:
forming a sacrificial gate stack on a channel region of a first layer of a substrate;
forming a spacer adjacent to the sacrificial gate stack;
forming a doped source/drain extension region in the first layer of the substrate prior to forming a raised source/drain region on the first layer of the substrate adjacent to the spacer;
forming a silicide region on the source/drain region;
forming a dielectric layer over the raised source/drain region after forming the silicide region on the source/drain region;
removing the sacrificial gate stack to expose the channel region of the first layer of the substrate; and
implanting dopants in a second layer of the substrate to form an implant region in the second layer below the channel region of the first layer of the substrate, where the first layer of the substrate is arranged on the second layer of the substrate.

9. The method of claim 1, wherein the sacrificial gate stack includes a polysilicon material.

10-20. (canceled)

21. The method of claim 8, further comprising forming a metal gate stack on the channel region of the first layer of the substrate.

22. The method of claim 8, wherein the forming the raised source/drain region includes growing a doped semiconductor material on an exposed portion of the first layer of the substrate.

23. The method of claim 8, wherein the dopants include p-type dopants.

24. The method of claim 8, wherein the sacrificial gate stack includes a polysilicon material.

25. The method of claim 8, wherein the raised source/drain region is formed on the first layer of the substrate adjacent to the spacer after forming the spacer adjacent to the sacrificial gate stack.

26. The method of claim 1, wherein the first layer of the substrate includes a III-V semiconductor material layer.

27. The method of claim 4, further comprising forming a metal gate stack on the channel region of the first layer of the substrate.

28. The method of claim 4, wherein the forming the raised source/drain region includes growing a doped semiconductor material on an exposed portion of the first layer of the substrate.

29. The method of claim 4, wherein the dopants include p-type dopants.

30. The method of claim 4, wherein the sacrificial gate stack includes a polysilicon material.

31. The method of claim 4, wherein the raised source/drain region is formed on the first layer of the substrate adjacent to the spacer after forming the spacer adjacent to the sacrificial gate stack.
